(19) United States
(12) Patent Application Publication
(10) Pub. No.: US 2026/0047464 A1
(43) Pub. Date: Feb. 12, 2026

(54) SEMICONDUCTOR PACKAGE

(71) Applicant: Samsung Electronics Co., Ltd., Suwon-si (KR)

(72) Inventors: Jangwoo LEE, Suwon-si (KR); Jongbo SHIM, Suwon-si (KR)

(73) Assignee: Samsung Electronics Co., Ltd., Suwon-si (KR)

(21) Appl. No.: 19/050,309

(22) Filed: Feb. 11, 2025

(30) Foreign Application Priority Data
Aug. 8, 2024 (KR) 10-2024-0106423

(51) Int. Cl. H01L 23/13; H01L 23/00; H01L 23/367; H01L 23/498; H01L 23/538; H01L 25/065; H01L 25/10; H01L 25/18; H10B 80/00; H10D 80/30

(52) U.S. Cl. CPC H01L 23/13; H01L 23/3675; H01L 23/49816; H01L 23/5385; H01L 24/16; H01L 24/32; H01L 24/73; H01L 25/0657; H01L 25/105; H01L 25/18; H01L 24/48; H01L 2224/16227; H01L 2224/32225; H01L 2224/48145; H01L 2224/48227; H01L 2224/73204; H01L 2225/06506; H01L 2225/0651; H01L 2225/06562; H01L 2225/1023; H01L 2225/1041; H01L 2225/1058; H01L 2924/1431; H10B 80/00; H10D 80/30

(57) ABSTRACT

A semiconductor package including a first package substrate having a first surface and a second surface, the second surface being opposite to the first surface; a first semiconductor chip on the second surface of the first package substrate; an interposer including a third surface and a fourth surface, the fourth surface being opposite to the third surface, and the third surface facing the first semiconductor chip; a second package substrate on the interposer, and a connection terminal being between the second package substrate and the interposer; and a second semiconductor chip on the second package substrate. The interposer defines a cavity that is an indentation in at least a portion of the fourth surface, and the connection terminal is in the cavity.

### CROSS-REFERENCE TO RELATED APPLICATION(S)

This application claims the benefit of Korean Patent Application No. 10-2024-0106423, filed on Aug. 8, 2024, in the Korean Intellectual Property Office, the disclosure of which is incorporated herein by reference in its entirety.

### BACKGROUND

Some example embodiments of the inventive concepts relate to semiconductor packages, and more particularly, to semiconductor packages having a package on package (POP) structure.

Due to the development of the electronics industry, the use of high-performance, high-speed and miniaturized electronic components is increasing, and the integration level of semiconductor chips is increasing. In response to the trend toward high integration and miniaturization of semiconductor chips, research and development are continuously being conducted on semiconductor packages that have a package-on-package structure (hereinafter, “POP packages”) in which at least two individual packages are stacked to form a single integrated package. Since the POP package is a structure in which two individual packages are laminated using solders or the like, the overall height of the POP package may be higher than that of other packages. Accordingly, the mounting height of the POP package may increase when mounted on an external printed circuit board (PCB), and so on. The increase in mounting height leads to an increase in the size of the finished electronic component, and if there is not enough space for the POP package to be mounted within the electronic component, the POP package may not be mounted on a PCB and so on. Since a gap is formed between the packages by solders or other means that join the individual packages and heat generated from the packages becomes trapped in the gap, thermal resistance of the semiconductor package may increase, which may reduce the durability and reliability of the semiconductor package.

### SUMMARY

Some example embodiments of the inventive concepts provide a semiconductor package of which mounting height is reduced (and/or minimized).

Some example embodiments provide a semiconductor package in which heat dissipation characteristics are improved.

Some example embodiments are not limited to advantages described above, and other advantages not described will be apparent to those skilled in the art from the present specification and the accompanying drawings.

Some example embodiments provide a semiconductor package that includes a first package substrate including a first surface and a second surface, the second surface being opposite to the first surface; a first semiconductor chip on the second surface of the first package substrate; an interposer including a third surface and a fourth surface, the fourth surface being opposite to the third surface, and the third surface facing the first semiconductor chip; a second package substrate on the interposer, and a connection terminal being between the second package substrate and the interposer; and a second semiconductor chip on the second package substrate. The interposer defines a cavity that is an indentation in at least a portion of the fourth surface, and the connection terminal is in the cavity.

Some example embodiments further provide a semiconductor package that includes an interposer including a first surface and a second surface, the second surface being opposite the first surface, and the interpose defining a cavity that is an indentation in at least a portion of the second surface being; a structure on the second surface of the interposer; a plurality of connecting structures in the cavity, and the plurality of connecting structures being configured to electrically connect the interposer and the structure; and an underfilling film configured to fill a gap between the interposer and the structure.

Some example embodiments still further provide a semiconductor package that includes a first package substrate including a first surface and a second surface, the second surface being opposite to the first surface; a first semiconductor chip on the second surface of the first package substrate; an interposer including a third surface and a fourth surface, the third surface facing the first semiconductor chip, the fourth surface being opposite to the third surface, and the interposer defining a cavity that is an indentation in at least a portion of the fourth surface; conductive connecting bodies surrounding the first semiconductor chip, the conductive conducting bodies being configured to vertically connect the first package substrate and the interposer; a second package substrate on the fourth surface of the interposer; a second semiconductor chip on the second package substrate; a connection terminal inside the cavity, the connection terminal being electrically connected to a conductive connecting body from among the conductive connecting bodies; and an underfilling film configured to fill a gap between the interposer at the cavity and the second package substrate. The cavity is in an area vertically overlapping with an area of the connection terminal.

Some example embodiments will be set forth in part in the description which follows and, in part, will be apparent from the description, or may be learned by practice of the disclosure.

According to some example embodiments, it is possible to minimize the mounting height of a semiconductor package.

According to some example embodiments, it is possible to increase the durability and reliability of a semiconductor package by improving the heat dissipation characteristics of the semiconductor package.

According to some example embodiments, it is possible to easily fill gaps between packages with an underfilling film by utilizing the capillary phenomenon.

The advantages of some example embodiments are not limited to the above-described advantages, and other advantages not described would be clearly understood by those skilled in the art from the description of the claims.

### BRIEF DESCRIPTION OF THE DRAWINGS

These and/or other aspects, features, and advantages of the inventive concepts will become apparent and more readily appreciated from the following description of some example embodiments, taken in conjunction with the accompanying drawings of which:

FIG. 1 is a plan view schematically illustrating a semiconductor package according to some example embodiments;

FIG. 2 is a plan view schematically illustrating a first package according to some example embodiments;

FIG. 3 is a cross-sectional view schematically illustrating a cross-section cut along line I-I′ of FIG. 1;

FIG. 4 is an enlarged view of a portion A of FIG. 3;

FIG. 5 is a cross-sectional view schematically illustrating a semiconductor package according to some example embodiments;

FIG. 6 is an enlarged view of a portion B of FIG. 5;

FIG. 7 is a cross-sectional view schematically illustrating a semiconductor package according to some example embodiments;

FIG. 8 is a cross-sectional view schematically illustrating a semiconductor package according to some example embodiments;

FIG. 9 is a cross-sectional view schematically illustrating a semiconductor package according to some example embodiments;

FIG. 10 is a plan view schematically illustrating a package according to some example embodiments;

FIG. 11 is a cross-sectional view schematically illustrating a semiconductor package including the package of FIG. 10; and

FIG. 12 is a cross-sectional view schematically illustrating a semiconductor package according to some example embodiments.

### DETAILED DESCRIPTION

Some example embodiments of the present disclosure described below can be modified and implemented in various forms. Technical ideas of the present disclosure are not limited to the some example embodiments described below. With regard to the terms used in the present disclosure, except for the case of terms described in detail in the present disclosure, the currently widely used general terms are selected as much as possible while taking into account the function in the present disclosure. However, terms may vary depending on the intention of a person skilled in the art to which the present disclosure pertains, case law, or the emergence of new technologies. Further, terms and words used in the present disclosure and claims should not be construed as limited to their ordinary or dictionary meanings, and the terms and words should be interpreted to include meanings and concepts consistent with the technical idea of the present disclosure.

In the present disclosure, the terms “comprise,” “include” or “have,” unless otherwise specifically stated, should be understood as meaning that it may include other components, rather than excluding other components. For example, it will be further understood that the terms “comprise,” “include” or “have” when used herein, specify the presence of stated features, integers, steps, operations, elements, and/or components, but do not preclude the presence or addition of one or more other features, integers, steps, operations, elements, components, and/or groups thereof.

In the present disclosure, singular expressions include plural expressions unless the context clearly indicates otherwise. Further, terms “first,” “second” and so on may be used to describe various components. However, the components are not limited by the terms, and the terms may be used for the purpose of distinguishing one component from another. Within the scope of the technical ideas of the present disclosure, the first component may be named as the second component. Similarly, the second component may also be named the first component. Further, the shape and size of components may be exaggerated to emphasize clear explanation. Further, in the following description, expressions such as “upper side,” “lower side,” “upper portion,” “lower portion,” “side,” “upper surface” and “lower surface” are expressed based on the direction shown in the drawing. If the direction of the object changes, it may be expressed differently.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

In the following specification, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, some example embodiments of the present inventive concepts are described in detail with reference to the attached drawings so that a person having ordinary skill in the art to which the present inventive concepts pertain can easily practice the present disclosure.

A semiconductor package 10 according to some example embodiments described below may be a semiconductor package of the package-on-package type that electrically connects multiple packages by stacking the packages. However, the semiconductor package 10 is not limited thereto, and it is apparent that the semiconductor package 10 may include various types of semiconductor packages other than the POP type semiconductor package. To help understanding, the following explanation uses some example embodiments in which the semiconductor package 10 is a POP type.

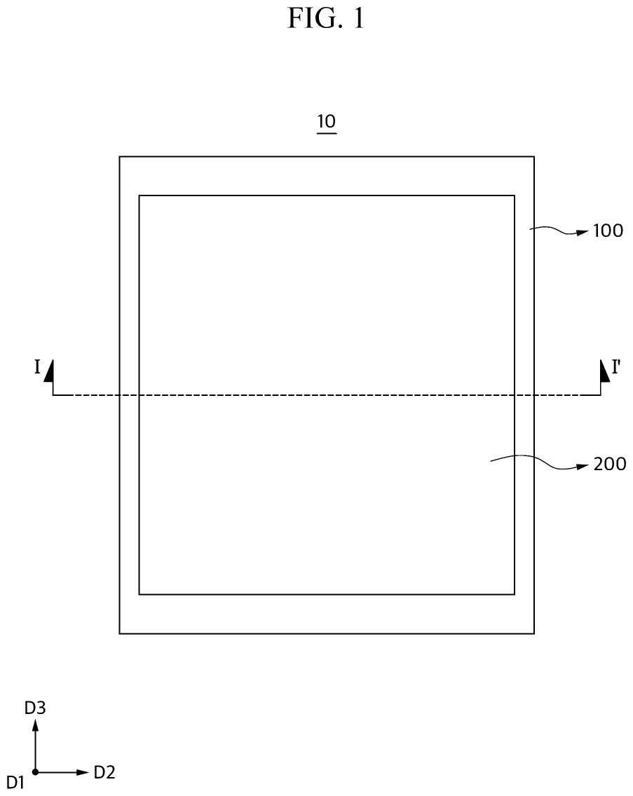

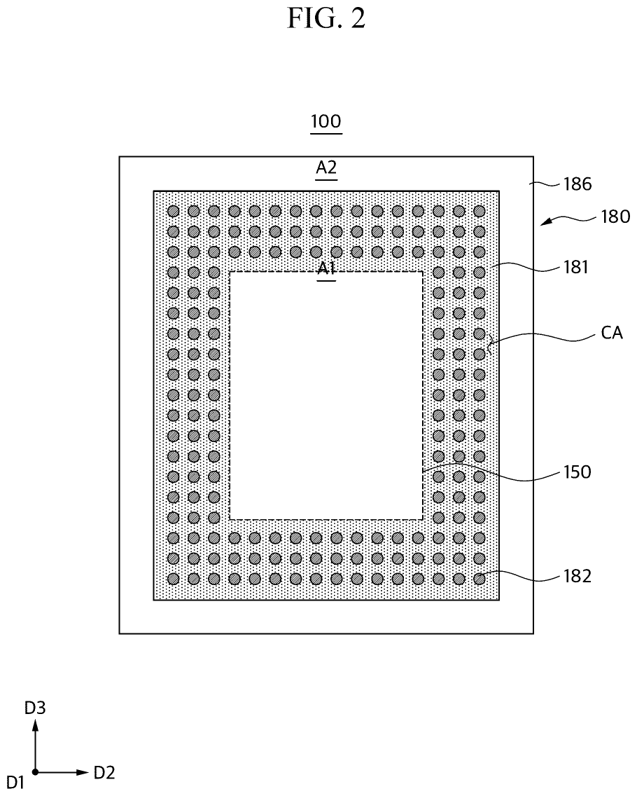

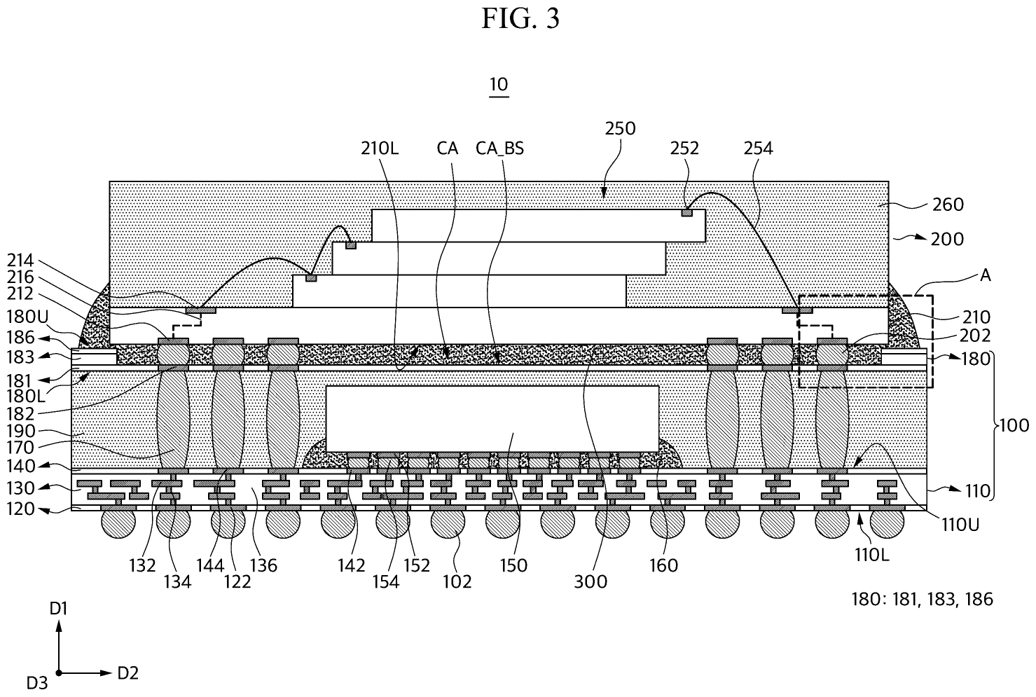

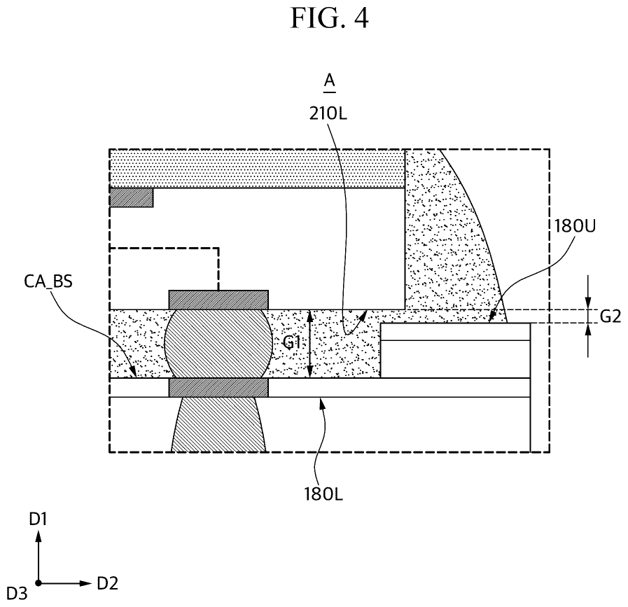

FIG. 1 is a plan view schematically illustrating a semiconductor package according to some example embodiments. FIG. 2 is a plan view schematically illustrating the first package of FIG. 1. FIG. 3 is a cross-sectional view schematically illustrating a cross-section cut along line I-I′ of FIG. 1. FIG. 4 is an enlarged view of the portion A of FIG. 3. To help understanding, some areas described below are shaded in FIG. 2. In FIG. 3, the illustration of wiring lines formed within an interposer wiring layer 183 described later are omitted.

Referring to FIGS. 1 to 4, the semiconductor package 10 according to some embodiments may include a first package 100 and a second package 200. The first package 100 and the second package 200 may be placed in one direction. Hereinafter, the direction in which the first package 100 and the second package 200 are placed is defined as the first direction D1, and the direction perpendicular to the first direction D1 when the semiconductor package 10 is viewed from a side is defined as the second direction D2. Further, the direction perpendicular to the plane containing both the first direction D1 and the second direction D2 is defined as the third direction D3. In some example embodiments, the first direction D1 may be perpendicular to the ground. Further, in some example embodiments, the second package 200 may be placed on the upper side of the first package 100 in the first direction D1, and may be mounted on the first package 100.

The first package 100 in some example embodiments may include a first package substrate 110, a first semiconductor chip 150 and an interposer 180. The first package substrate 110 in some example embodiments may be a wiring board for a package. For example, the first package substrate 110 may be a PCB or a ceramic substrate. Further, the first package substrate 110 may be a wiring substrate. However, the first package substrate 110 is not limited thereto, and the first package substrate 110 may be a wiring substrate for a wafer level package (WLP) manufactured at the wafer level. When the first package substrate 110 is the PCB, the first package substrate 110 may include at least one material selected from tetrafunctional epoxy, polyphenylene ether, epoxy/polyphenylene oxide, bismaleimide triazine (BT), THERMOUNT® (a nonwoven aramid fiber reinforced substrate for printed wiring boards), cyanate ester, and liquid crystal polymer. Further, the first package substrate 110 may include a resin impregnated into a core material such as glass fiber (glass cloth and glass fabric) along with an inorganic filler, the resin such as prepreg, an ajinomoto build-up film (ABF), FR. −4, and BT. However, the first package substrate 110 is not limited to the some example embodiments, and it is apparent that the first package substrate 110 may include various types of substrates. To help understanding, some example embodiments are described below in which the first package substrate 110 is a PCB in which insulation layers and wiring layers are alternately laminated.

In some example embodiments, the first package substrate 110 may include a first surface 110L and a second surface 110U. In some example embodiments, the first surface 110L and the second surface 110U may be opposite surfaces. Further, in some example embodiments, the first surface 110L may be provided with a first connection terminal 102, as described below, and the first semiconductor chip 150, described later, may be placed on the second surface 110U.

In some example embodiments, the first package substrate 110 may include a first insulation layer 120, a wiring layer 130 and a second insulation layer 140. In some example embodiments, the first insulation layer 120 may include the first surface 110L, and the second insulation layer 140 may include the second surface 110U. In some example embodiments, the first insulation layer 120, the wiring layer 130 and the second insulation layer 140 may be sequentially arranged in the first direction D1. Further, for example, the first insulation layer 120 may be located on the lower portion of the first package substrate 110, and the second insulation layer 140 may be located on the upper portion of the first package substrate 110. In some example embodiments, the wiring layer 130 may be located between the first insulation layer 120 and the second insulation layer 140, and a wiring line (a wiring pattern 132 and a wiring via 134) may be formed inside. The wiring line (the wiring pattern 132 and the wiring via 134) may include a conductive material. For example, the wiring line (the wiring pattern 132 and the wiring via 134) may include at least one of copper (Cu), aluminum (Al), tin (Sn), indium (In), lead (Pb), zinc (Zn), nickel (Ni), titanium (Ti), gold (Au), silver (Ag), antimony (Sb), or bismuth (Bi) and combinations thereof. However, the wiring line is not limited thereto. In some example embodiments, the wiring line (the wiring pattern 132 and the wiring via 134) may include the wiring pattern 132 and the wiring via 134. In some example embodiments, the wiring pattern 132 may be extended in the second direction D2 and/or in the third direction D3. Further, the wiring via 134 may be extended in the first direction D1. The wiring pattern 132 may be placed on the same layer. Alternatively, the wiring pattern 132 may be arranged in layers spaced apart in the first direction D1. The wiring via 134 may vertically connect wiring patterns 132, each of which is arranged in a layer separated in the first direction D1. For example, the wiring line (the wiring pattern 132 and the wiring via 134) may have a multilayer structure in which at least one wiring pattern 132 and at least one wiring via 134 are alternately stacked. The number, placement and/or arrangement of the wiring line (the wiring pattern 132 and the wiring via 134) is not limited to what is illustrated in FIG. 3, and the wiring pattern 132 and the wiring via 134 may be included in a different number, placement and/or arrangement.

In some example embodiments, the wiring line (the wiring pattern 132 and the wiring via 134) may be surrounded by a middle insulation layer 136. For example, the middle insulation layer 136 may be placed to surround the wiring line (the wiring pattern 132 and the wiring via 134) that is a single layer structure or a multi-layer structure. In some example embodiments, the first insulation layer 120, the middle insulation layer 136 and the second insulation layer 140 may include organic materials such as photo imageable dielectric (PID) materials and photosensitive polyimide (PSPI) materials. For example, the PID material may include at least one of PSPI, polybenzoxazole, phenol-based polymer, and benzocyclobutene-based polymer. In some example embodiments, a lower portion insulation layer (not illustrated) may be formed of an inorganic dielectric material, such as silicon nitride and silicon oxide. In some example embodiments, the first insulation layer 120 and the second insulation layer 140 may be solder resist layers that protect the wiring layer 130 from external physical and/or chemical damage. In some example embodiments, the solder resist layer may contain an insulating material. The solder resist layer may be formed using, for example, prepreg, ABF, FR-4, BT, or photo solder resist (PSR).

In some example embodiments, a first package pad 122 may be placed on the first insulation layer 120. Further, a first connection pad 142 and a second connection pad 144 may be placed in the second insulation layer 140. Each of the first package pad 122, the first connection pad 142 and the second connection pad 144 may include a conductive material. For example, each of the first package pad 122, the first connection pad 142 and the second connection pad 144 may include aluminum (Al), copper (Cu) and so on. In some example embodiments, each of the first package pad 122, the first connection pad 142 and the second connection pad 144 may be electrically connected to the wiring line (the wiring pattern 132 and the wiring via 134). Further, the first connection terminal 102 configured to be electrically connected to an external device on which the semiconductor package 10 is mounted may be placed on the first package pad 122. In some example embodiments, the first connection terminal 102 may include a conductive material and may have a spherical or oval shape, but the shape of the first connection terminal 102 is not limited thereto.

In some example embodiments, the first connection pad 142 may be generally located in the central area of the first package substrate 110 when viewed from the first direction D1. Further, when viewed from the first direction D1, the second connection pad 144 may generally be located at the edge area of the first package substrate 110. For example, the first connection pad 142 may come into contact with a first pad 152 arranged on the lower portion side of the first semiconductor chip 150 so as to be electrically connected to the first semiconductor chip 150 described later, and the second connection pad 144 may make contact with a conductive connecting body 170 described below. The number, placement and/or a cross-sectional shape of the first package pad 122, the first connection pad 142 and the second connection pad 144 is not limited what is illustrated in FIG. 3.

In some example embodiments, the first semiconductor chip 150 may be placed on the first package substrate 110. For example, in the first direction D1, the first semiconductor chip 150 may be placed on the upper side of the first package substrate 110. Accordingly, the first semiconductor chip 150 may be mounted on the second surface 110U of the first package substrate 110. Further, the first semiconductor chip 150 may be placed between conductive connecting bodies 170 described later in the second direction D2 and/or in the third direction D3. In some example embodiments, the first semiconductor chip 150 may include a logic chip. For example, a logic chip may include a microprocessor, analog devices, or a digital signal processor. In some example embodiments, the logic chip may include an application processor (AP). Further, the logic chip may be a microprocessor such as a central processing unit (CPU) and graphic processing unit (GPU), an analog device, or a digital signal processor. However, the first semiconductor chip 150 is not limited thereto, and may further include a system on chip (SOC) that is a single chip in which all essential elements of the system, including memory chips, image chips including CCD image sensors or CMOS image sensors, microprocessors, memory, and/or input/output interfaces, are integrated. Further, the first semiconductor chip 150 may further include a system-in-package (SIP) that integrates multiple integrated circuits into a single package. To help understanding, some example embodiments are given below where the first semiconductor chip 150 is a logic chip.

In some example embodiments, the first semiconductor chip 150 may include a substrate and a wiring structure. The substrate of the first semiconductor chip 150 may include silicon (Si), for example, crystalline silicon, polycrystalline silicon, or amorphous silicon. Alternatively, the substrate of the first semiconductor chip 150 may include a semiconductor element such as germanium (Ge), or a compound semiconductor such as silicon carbide (SiC), gallium arsenide (GaAs), indium arsenide (InAs) and indium phosphide (InP). The substrate of the first semiconductor chip 150 may have a silicon on insulator (SOI) structure. For example, the substrate of the first semiconductor chip 150 may include a buried oxide layer (BOX layer). The substrate of the first semiconductor chip 150 may include a conductive region. For example, a doped well or a doped structure may be included. Further, the substrate of the first semiconductor chip 150 may have various device isolation structures, such as a shallow trench isolation (STI) structure. In some example embodiments, the wiring structure of the first semiconductor chip 150 may be located on the lower side of the substrate of the first semiconductor chip 150 in the first direction D1. The wiring structure of the first semiconductor chip 150 may include multilayer patterns, vias that vertically connect multilayer patterns and an insulation layer for insulating the multilayer patterns and the vias. The insulation layer may have a single-layer structure or a multi-layer structure, and the patterns and the vias may include a conductive material. In some example embodiments, the first semiconductor chip 150 may include at least one circuit device, and the circuit device of the first semiconductor chip 150 may be electrically connected to the pattern and the via of the first semiconductor chip 150.

In some example embodiments, the first pad 152 may be placed on the first semiconductor chip 150. For example, a plurality of first pads 152 may be placed on a lower surface of the first semiconductor chip 150. The plurality of first pads 152 may be spaced apart from each other, and each of the plurality of first pads 152 may be positioned at a one-to-one matching position with the second connection pads 144 arranged on the first package substrate 110. Further, the first pad 152 may include a conductive material identical or similar to the first connection pad 142 described above.

In some example embodiments, a first bump 154 may be placed on the first pad 152. For example, the first bump 154 may be placed between the first pad 152 and the first connection pad 142. The first bump 154 may contain a conductive material identical or similar to that of the first pad 152, and may have various shapes such as a land, a ball, a pin, pillar and so on. The number, spacing and arrangement of the first pad 152 and the first bump 154 are not limited what is illustrated, and it is apparent that the number, spacing and arrangement of the first pad 152 and the first bump 154 may vary depending on the design. In some example embodiments, the circuit device of the first semiconductor chip 150 may be electrically connected to the first package substrate 110 via the first pad 152, the first bump 154 and the first connection pad 142 described above, and accordingly, the circuit device of the first semiconductor chip 150 may transmit and receive electrical signals with an external device.

In some example embodiments, a first underfilling film 160 may be interposed between the first semiconductor chip 150 and the first package substrate 110. For example, a gap between the first semiconductor chip 150 and the first package substrate 110 may be filled by the first underfilling film 160. For example, the first underfilling film 160 may be injected into the gap between the first semiconductor chip 150 and the first package substrate 110 by the capillary phenomenon, and may cover at least a portion of the first pad 152 arranged on the lower portion side of the first semiconductor chip 150, at least a portion of the first bump 154, a lower surface and at least a portion of one side of the first semiconductor chip 150, and at least a portion of an upper surface of the first package substrate 110. In some example embodiments, the first underfilling film 160 may contain an epoxy-based resin. Further, the first underfilling film 160 contains an epoxy-based resin as a base material, and may further include a curing agent including an amine and phenol series material, a filler including silica (SiO₂), and/or various additives added according to design requirements.

In some example embodiments, the plurality of conductive connecting bodies 170 may be placed on a side of the first semiconductor chip 150. Further, the plurality of conductive connecting bodies 170 may be spaced apart in the second direction D2 and the third direction D3. For example, in the second direction D2 and the third direction D3, the plurality of conductive connecting bodies 170 may be arranged to surround the first semiconductor chip 150. Further, the plurality of conductive connecting bodies 170 may be placed on the first package substrate 110. For example, the plurality of conductive connecting bodies 170 may be placed between the first package substrate 110 and a second package substrate 210 described below. When viewed in the first direction D1, the plurality of conductive connecting bodies 170 may generally be placed on the edge area of the first package substrate 110. In some example embodiments, in the first direction D1, the plurality of conductive connecting bodies 170 may be formed in an area overlapping a second connection terminal 202 described below. Further, the plurality of conductive connecting bodies 170 may be placed on the second connection pad 144. For example, the bottom of the conductive connecting body 170 may come into contact with the top of the second connection pad 144, and the top of the conductive connecting body 170 may contact the lower part of a third connection pad 182 described later.

In some example embodiments, the conductive connecting body 170 has a longitudinal direction generally parallel to the first direction D1. The conductive connecting body 170 may include a conductive material. For example, the conductive connecting body 170 may include tin (Sn), silver (Ag), or copper (Cu), or may include alloys thereof. Accordingly, the conductive connecting body 170 may be electrically connected to the third connection pad 182 formed on a lower portion of the interposer 180 described later, and the second connection pad 144 formed on the upper portion of the first package substrate 110. In some example embodiments, the conductive connecting body 170 may be formed by forming a via in a first molding layer 190 described below and then filling the via with the solder. According to some example embodiments, the conductive connecting body 170 may be a wiring post. However, the conductive connecting body 170 is not limited thereto. The conductive connecting body 170 may be any of the known vertical connecting bodies that electrically connect the second connection pad 144 and the third connection pad 182.

In some example embodiments, in the first direction D1, the interposer 180 may be placed on the upper side of the first package substrate 110 and the first semiconductor chip 150. For example, in the first direction D1, the interposer 180 may be spaced apart from the first semiconductor chip 150 at a distance on the upper side. In some example embodiments, the interposer 180 may have a third surface 180L and a fourth surface 180U. For example, the third surface 180L and the fourth surface 180U may be opposite surfaces along the first direction D1. Further, the third surface 180L may be the lower surface of the interposer 180, and the fourth surface 180U may be the upper surface of the interposer 180. In some example embodiments, the third surface 180L may be arranged to face the upper surface of the first semiconductor chip 150, and the fourth surface 180U may be arranged to face a lower surface 210L of the second package substrate 210 described later.

In some example embodiments, the interposer 180 may transmit and distribute signals between the first semiconductor chip 150 and a second semiconductor chip 250 described later. For example, the interposer 180 may include a silicon interposer, an organic interposer, a glass interposer, a ceramic interposer and so on. However, the interposer 180 is not limited thereto. In some example embodiments, the interposer 180 may include either a PCB or a redistribution substrate (or a redistribution layer).

In some example embodiments, the interposer 180 may include a first interposer insulation layer 181, the interposer wiring layer 183 and a second interposer insulation layer 186. In some example embodiments, the first interposer insulation layer 181, the interposer wiring layer 183 and the second interposer insulation layer 186 may be sequentially laminated along the first direction D1. For example, the interposer wiring layer 183 may be laminated to the upper side of the first interposer insulation layer 181, and the second interposer insulation layer 186 may be laminated to the upper side of the interposer wiring layer 183. Further, in some example embodiments, the first interposer insulation layer 181 may include the third surface 180L described above, and the second interposer insulation layer 186 may include the fourth surface 180U described above. For example, the lowest surface of the first interposer insulation layer 181 may be the third surface 180L, and the uppermost surface of the second interposer insulation layer 186 may be the fourth surface 180U.

In some example embodiments, the first interposer insulation layer 181 and the second interposer insulation layer 186 may include materials identical or similar to the first insulation layer 120 described above. Further, the first interposer insulation layer 181 and the second interposer insulation layer 186 may be solder resist layers that protect the interposer wiring layer 183 from the external environment. Further, the interposer wiring layer 183 may include materials identical or similar to the wiring layer 130 described above, and the interposer wiring layer 183 may form interposer wiring lines that are not illustrated. Further, an insulation layer may be formed in the interposer wiring layer 183 to wrap the wiring lines in a single-layer structure or a multi-layer structure. Further, in some example embodiments, the third connection pad 182 containing a conductive material may be placed on the first interposer insulation layer 181. The third connection pad 182 may be electrically connected between the conductive connecting body 170 and the second connection terminal 202 described later. As with the first pad 152 described above, a plurality of third connection pads 182 may be placed spaced apart from each other. Each of the plurality of third connection pads 182 may be positioned in a one-to-one matching position with the conductive connecting bodies 170.

In some example embodiments, the interposer 180 may include a cavity CA. In some example embodiments, the cavity CA may be formed on the fourth surface 180U. For example, the cavity CA may be a space formed by indentation from the fourth surface 180U toward the third surface 180L. For example, the interposer 180 may define a cavity CA that is an indentation in at least apportion of the fourth surface 180U. Accordingly, the vertical distance from the third surface 180L of the interposer 180 to a bottom surface CA_BS of the cavity CA may be smaller than the vertical distance from the third surface 180L of the interposer 180 to the fourth surface 180U of the interposer 180. Further, as illustrated in FIG. 4, in some example embodiments, the bottom surface CA_BS of the cavity CA may be located on the same virtual plane as the upper surface of the first interposer insulation layer 181. For example, the vertical distance from the third surface 180L to the bottom surface CA_BS of the cavity CA may be the same as the vertical distance from the third surface 180L to the upper surface of the first interposer insulation layer 181. However, the present disclosure is not limited thereto. In the first direction D1, the bottom surface CA_BS of the cavity CA may be located between the upper surface and the lower surface of the first interposer insulation layer 181.

In some example embodiments, the cavity CA may be formed at a portion or portions of the interposer 180. For example, in some example embodiments, the cavity CA may be formed in a core area A1 and a sub area A2 of the interposer 180, when viewed in the first direction D1. Here, the core area A1 may indicate an area including the center of the third surface 180L or the fourth surface 180U, and the sub area A2 may refer to the area surrounding the core area A1. Further, in some example embodiments, the core area A1 may be an area overlapping the first semiconductor chip 150 and the conductive connecting body 170 described above when viewed from the first direction D1. The core area A1 may indicate an area including an area facing an area in which the second connection terminal 202 is formed in the first direction D1.

In some example embodiments, the first molding layer 190 may cover at least a portion of the first package substrate 110, at least a portion of the first semiconductor chip 150, and at least a portion of the interposer 180. For example, the first molding layer 190 may cover at least a portion of an upper surface of the first package substrate 110, an upper surface, at least a portion of a lower surface and sides of the first semiconductor chip 150, sides of the conductive connecting body 170, at least a portion of the third surface 180L of the interposer 180, at least a portion of the upper surface of the second connection pad 144, and at least a portion of an upper surface of the third connection pad 182. In some example embodiments, the first molding layer 190 may be a resin including epoxy or polyimide. For example, the resin may include bisphenol-group epoxy resin, polycyclic aromatic epoxy resin, o-cresol novolac epoxy resin, biphenylgroupepoxy resin or naphthalene-group epoxy resin. The first molding layer 190 in some example embodiments may be an epoxy molding compound. However, the first molding layer 190 is not particularly limited to the some example embodiments described above.

In some example embodiments, the second package 200 may include the second package substrate 210 and the second semiconductor chip 250. In some example embodiments, the second package 200 may be smaller in width than the first package 100. However, the present disclosure is not limited thereto. The width of the first package 100 and the width of the second package 200 may be approximately the same, and the width of the second package 200 may be larger than the width of the first package 100. Below, to help understanding, some example embodiments are given where the width of the second package 200 is smaller than the width of the first package 100.

In some example embodiments, the second package substrate 210 may be a substrate for a panel level package (PLP) manufactured at the panel level. However, the present disclosure is not limited thereto. The second package substrate 210 may be a substrate for WLP manufactured at the wafer level. Further, the second package substrate 210 may be a PCB or a redistribution substrate. In some example embodiments, the second package substrate 210 may be referred to as a structure.

In some example embodiments, the second package substrate 210 may include a second package pad 212, a second pad 214 and a wiring circuit 216. In some example embodiments, each of the second package pad 212, the second pad 214 and the wiring circuit 216 may include a conductive material. For example, the second package pad 212, the second pad 214 and the wiring circuit 216 may include copper (Cu). In some example embodiments, the second package pad 212 may be positioned on the lower portion of the second package substrate 210 and may be exposed on the lower surface 210L of the second package substrate 210. Further, the second pad 214 may be positioned on the upper portion of the second package substrate 210 and may be exposed on the upper surface of the second package substrate 210. Further, the wiring circuit 216 is arranged between the second package pad 212 and the second pad 214 to electrically connect the second package pad 212 and the second pad 214.

In some example embodiments, the second connection terminal 202 may be formed on the lower portion of the second package substrate 210. In some example embodiments, the second connection terminal 202 may include a conductive material, and the second connection terminal 202 may be a solder ball having a spherical or oval shape, but the second connection terminal 202 is not limited thereto. For example, it is apparent that the second connection terminal 202 may have various shapes such as a land, a ball, a pin, and pillar containing a conductive material. Further, in some example embodiments, the second connection terminal 202 may be referred to as a connecting structure.

In some example embodiments, at least one second connection terminal 202 may be placed on the second package pad 212. Further, in some example embodiments, the second connection terminal 202 may be accommodated within the cavity CA. The upper part of the second connection terminal 202 may contact the second package pad 212, and the lower part of the second connection terminal 202 may contact the third connection pad 182 described above. Accordingly, the second package substrate 210 may be mounted on the interposer 180, for example, the cavity CA, and may be electrically connected to the first package substrate 110 by the second connection terminal 202 and the conductive connecting body 170. However, the present disclosure is not limited to the shape and the arrangement of the second connection terminal 202 illustrated in FIG. 3.

In some example embodiments, the lower surface 210L of the second package substrate 210 may face the third surface 180L of the interposer 180. Further, the lower surface 210L of the second package substrate 210 may face the bottom surface CA_BS of the cavity CA. For example, in the first direction D1, a portion of the lower surface 210L of the second package substrate 210 (for example, an edge area of the lower surface 210L) may overlap the fourth surface 180U, and another portion (for example, the central area of the lower surface 210L) may overlap the bottom surface CA_BS of the cavity CA. For example, the second package substrate 210 may overlap the side of the cavity CA in the first direction D1. In some example embodiments, as illustrated in FIG. 3 and FIG. 4, in the state where the second connection terminal 202 is in contact with each of the third connection pad 182 and the second package pad 212, the lower surface 210L of the second package substrate 210 may be spaced apart from the fourth surface 180U of the interposer 180. For example, the lower surface 210L of the second package substrate 210 may be located on the upper side of the fourth surface 180U of the interposer 180, in the first direction D1. For example, the vertical distance from the first surface 110L of the first package substrate 110 to the lower surface 210L of the second package substrate 210 may be greater than a vertical distance from the first surface 110L of the first package substrate 110 to the fourth surface 180U of the interposer 180. Accordingly, a terminal gap G1 may be formed between the lower surface 210L of the second package substrate 210 and the bottom surface CA_BS of the cavity CA, and the second connection terminal 202 described above may be located in the terminal gap G1. Further, a filled gap G2 may be formed between the lower surface 210L of the second package substrate 210 and the fourth surface 180U of the interposer 180. In some example embodiments, the filled gap G2 may be narrower than the terminal gap G1. However, the present disclosure is not limited thereto. The filled gap G2 and the terminal gap G1 may be the same, and the filled gap G2 may be wider than the terminal gap G1.

In some example embodiments, the second semiconductor chip 250 may be mounted on the second package substrate 210. For example, the second semiconductor chip 250 may be mounted on the upper surface of the second package substrate 210, which is opposite to the lower surface 210L of the second package substrate 210. In some example embodiments, the second semiconductor chip 250 may include a logic chip and/or a memory chip. For example, the logic chip is largely identical or similar to that described in the first semiconductor chip 150 described above, and thus repeated descriptions are omitted. In some example embodiments, the memory chip may include a non-volatile memory chip. In some example embodiments, the memory chips may include non-volatile memory chips such as universal flash storage (UFS). Further, the memory chips may include volatile memory chips, such as dynamic random access memory (DRAM) and static random access memory (SRAM), and/or may include a non-volatile memory chip such as phase-change random access memory (PRAM), magneto-resistive random access memory (MRAM), ferroelectric random access memory (FeRAM), and resistive random access memory (RRAM). However, the memory chip is not limited thereto. The second semiconductor chip 250 may include a system on chip (SOC). Below, to help understanding, some example embodiments are given in which the second semiconductor chip 250 is a memory chip.

In some example embodiments, the second semiconductor chip 250 may include a substrate and a wiring structure. In some example embodiments, the wiring structure of the second semiconductor chip 250 may be located on the substrate of the second semiconductor chip 250. Regarding the arrangement, descriptions on a substrate of the second semiconductor chip 250 and a wiring structure of the second semiconductor chip 250 are very much similar or identical to the substrate and the wiring structure of the first semiconductor chip 150 described above, and thus repeated descriptions thereon are omitted. In some example embodiments, the second semiconductor chip 250 may include a bonding pad 252 and a bonding wire 254. In some example embodiments, the bonding pad 252 may include a conductive material. For example, the bonding pad 252 may contain copper (Cu). Further, at least one bonding pad 252 may be placed at an upper portion of the second semiconductor chip 250. The bonding wire 254 may be electrically connected to the bonding pad 252 and the second pad 214. For example, one end of the bonding wire 254 may be connected to the bonding pad 252, and the other end of the bonding wire 254 may be connected to the second pad 214. Accordingly, the second semiconductor chip 250 is mounted on the second package substrate 210 and may be electrically connected to the wiring circuit 216 of the second package substrate 210. In some example embodiments, a plurality of second semiconductor chips 250 may be mounted on the second package substrate 210. The plurality of second semiconductor chips 250 may be stacked along the first direction D1 on the second package substrate 210, and each of the plurality of second semiconductor chips 250 may be electrically connected to the second package substrate 210 by the bonding wire 254.

In the some example embodiments above, it is described that the second semiconductor chip 250 is wire-bonded onto the second package substrate 210, but it is apparent that the second semiconductor chip 250 may be mounted on the second package substrate 210 using a flip chip bonding method.

In some example embodiments, at least a portion of the second package substrate 210 and at least a portion of the second semiconductor chip 250 may be covered by a second molding layer 260. For example, the second molding layer 260 may cover the upper surface of the second package substrate 210, and cover the sides and at least a portion of the upper surface and at least a portion of the lower surface of the second semiconductor chip 250. In some example embodiments, the second molding layer 260 includes the same or substantially the same material or similar material as the first molding layer 190 described above, and thus repeated descriptions are omitted.

In some example embodiments, a second underfilling film 300 may be interposed between the first package 100 and the second package 200. For example, the space between the cavity CA (e.g., the bottom surface CA_BS of the cavity CA) and the lower surface 210L of the second package substrate 210 may be filled by the second underfilling film 300. For example, the second underfilling film 300 may be injected into the terminal gap G1, which is the space between the first package substrate 110 and the second package substrate 210, through the filled gap G2 by the capillary phenomenon, and cover sides of the second connection terminal 202, at least a portion of the bottom surface CA_BS and sides of the cavity CA, at least a portion of the fourth surface 180U of the interposer 180, at least a portion of the side of the second package substrate 210, and at least a portion of the side of the second molding layer 260. In some example embodiments, the second underfilling film 300 may contain the same or substantially the same material or similar materials as the first underfilling film 160 described above, and thus descriptions thereon are omitted.

As described above, the filled gap G2 may be narrower than the terminal gap G1. Thus, in the process of filling the gap between the first package 100 and the second package 200 with the second underfilling film 300, since the capillary phenomenon becomes more active, the material forming the second underfilling film 300 may flow more spontaneously from the filled gap G2 toward the terminal gap G1. Accordingly, the material constituting the second underfilling film 300 may easily penetrate between the second connection terminals 202 located in the terminal gap G1, and underfilling between the first package 100 and the second package 200 may be feasible or easy. Further, by reducing (and/or minimizing) the occurrence of voids such as air bubbles between the first package 100 and the second package 200, the phenomenon of heat generated in the first semiconductor chip 150 being trapped in the void and increasing thermal resistance may be reduced (and/or minimized), and the reliability of the semiconductor package 10 may be improved by alleviating mechanical stress that may occur due to expansion and contraction due to heat.

Further, according to some example embodiments, since the second connection terminal 202 formed on the lower portion of the second package substrate 210 is placed within the cavity CA, the overall height of the semiconductor package 10 may be reduced when the second package 200 is mounted on the first package 100. For example, the mounting height may be reduced by the height of the cavity CA, that is, by the terminal gap G1, when compared to the structure where the cavity CA is not formed. Further, since the cavity CA may perform some kind of a dam function, the structural stability of the second underfilling film 300 filled in the cavity CA may be improved.

Below, a semiconductor package according to some example embodiments is described. Except where otherwise stated, the semiconductor packages described have mostly the same or similar structure and function as the semiconductor packages 10 described above (see FIGS. 1 to 4), and thus repeated descriptions are omitted.

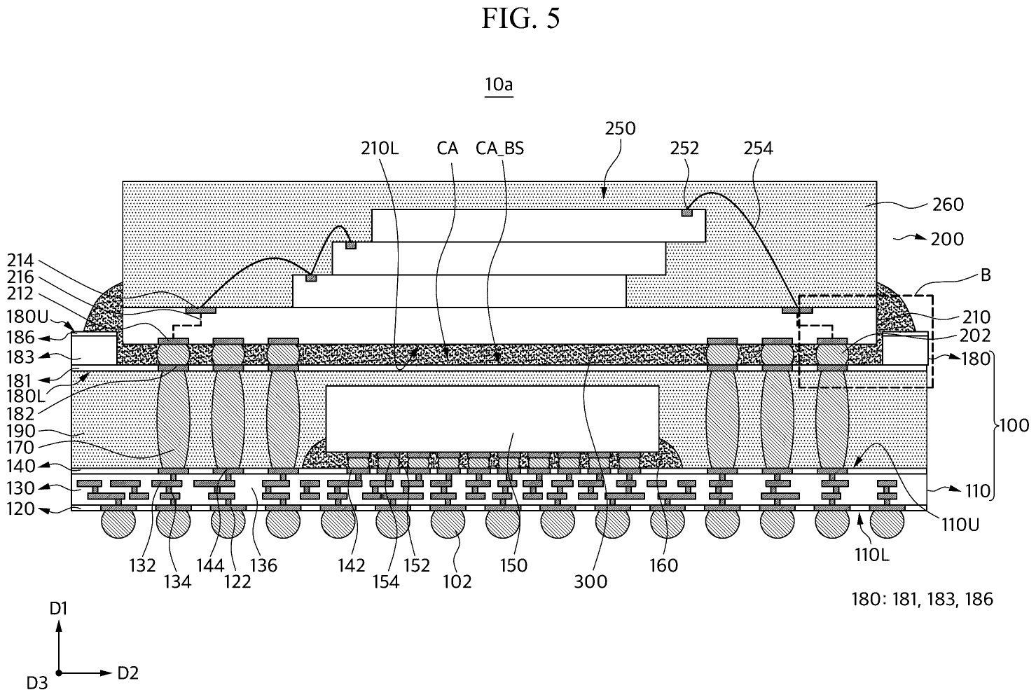

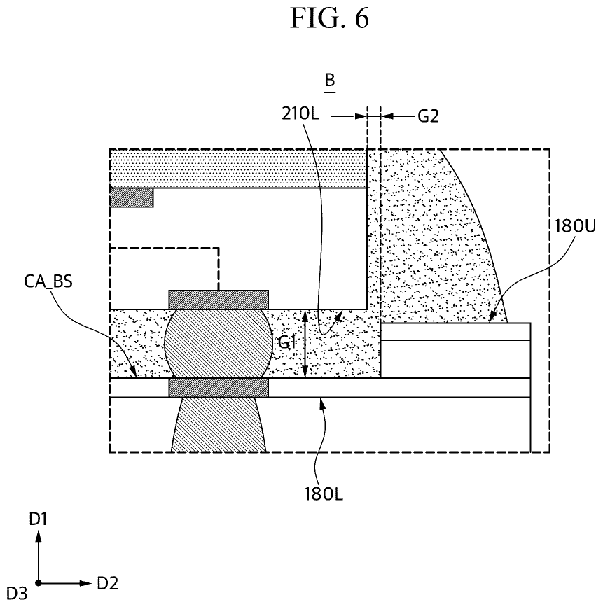

FIG. 5 is a cross-sectional view schematically illustrating a semiconductor package according to some example embodiments. FIG. 6 is an enlarged view of the portion B of FIG. 5.

Referring to a semiconductor package 10a according to some example embodiments of FIGS. 5 and 6, the lower surface 210L of the second package substrate 210 may be located on the lower side of the fourth surface 180U of the interposer 180 in the first direction D1. For example, the vertical distance from the first surface 110L of the first package substrate 110 to the lower surface 210L of the second package substrate 210 may be less than the vertical distance from the first surface 110L of the first package substrate 110 to the fourth surface 180U of the interposer 180. Further, in some example embodiments, the sides of the second package substrate 210 may be positioned apart from the sides of the cavity CA in the second direction D2 and/or the third direction D3. For example, the sides of the second package substrate 210 may be positioned inside the sides of the cavity CA in the second direction D2 and/or the third direction D3. In some example embodiments, the entire area of the lower surface 210L of the second package substrate 210 may overlap the bottom surface CA_BS of the cavity CA in the first direction D1. Further, in some example embodiments, the space between the sides of the second package substrate 210 and the sides of the cavity CA may be defined as the filled gap G2 described above, and the space between the lower surface 210L of the second package substrate 210 and the bottom surface CA_BS of the cavity CA may be defined as the terminal gap G1 described above.

According to some example embodiments, since the filled gap G2 is formed generally along the first direction D1 (for example, the gravity direction perpendicular to the ground), the constituent material of the second underfilling film 300 may more easily penetrate into the terminal gap G1. Since the entire structure of the second package 200 may be located inside the cavity CA (e.g., may overlap the cavity along the first direction D1), when the second package 200 is mounted on the first package 100, it may not be interfered with by the first package 100. Accordingly, since the terminal gap G1 may be designed to be narrower, the overall mounting height of the semiconductor package 10a may be further reduced.

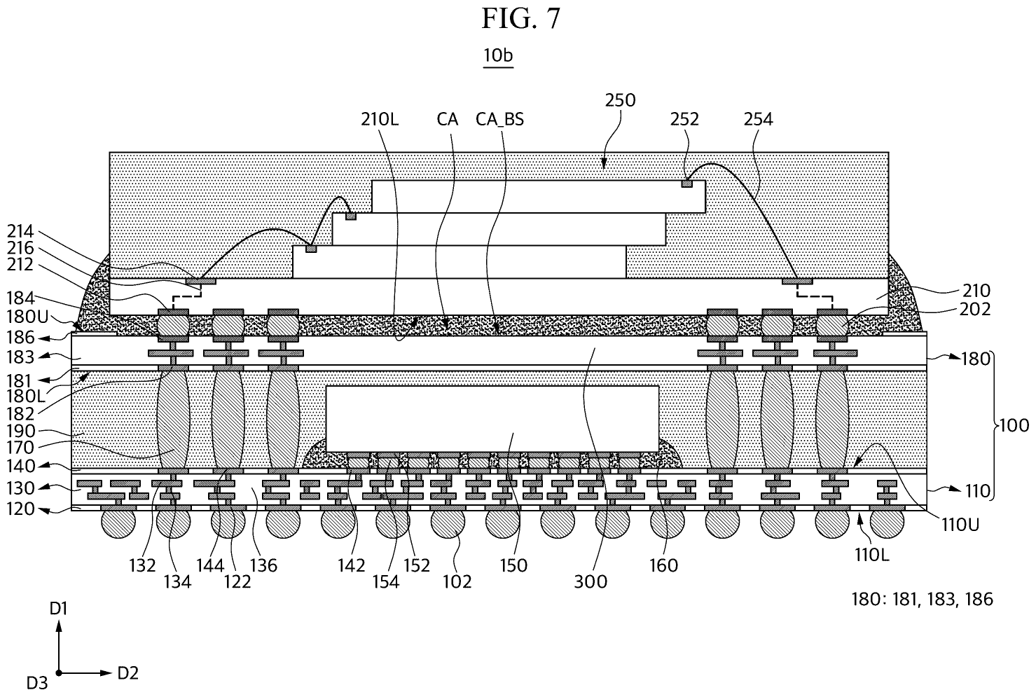

FIG. 7 is a cross-sectional view schematically illustrating a semiconductor package according to some example embodiments.

When referring to a semiconductor package 10b of some example embodiments, the interposer wiring layer 183 may include a wiring line 184. The wiring line 184 may have mostly the same or similar functions and structures as the wiring line (the wiring pattern 132 and the wiring via 134) formed in the wiring layer 130 of the first package substrate 110 described above, and thus repeated descriptions are omitted. In some example embodiments, the vertical distance from the third surface 180L of the interposer 180 to the bottom surface CA_BS of the cavity CA may be the same as the vertical distance from the third surface 180L of the interposer 180 to the upper surface of the interposer wiring layer 183. For example, the bottom surface CA_BS of the cavity CA may be located on the same virtual plane as the upper surface of the interposer wiring layer 183. Further, the second connection terminal 202 may come into contact with the wiring line 184 and thus be electrically connected.

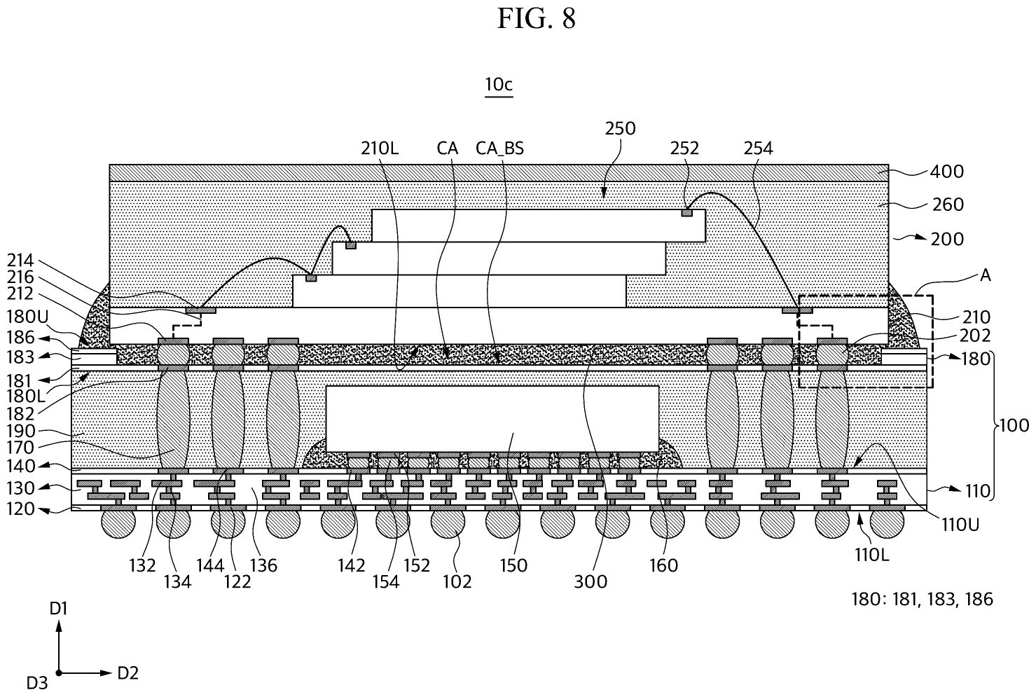

FIG. 8 is a cross-sectional view schematically illustrating a semiconductor package according to some example embodiments.

Referring to FIG. 8, a semiconductor package 10c according to some example embodiments may further include a heat dissipation structure 400. The heat dissipation structure 400 according to some example embodiments may dissipate heat generated in the second semiconductor chip 250 from the semiconductor package 10c. For example, the heat dissipation structure 400 may include a metal plate including a metal material having excellent thermal conductivity or a metal tape having flexibility. In some example embodiments, the heat dissipation structure 400 may be located on the second package 200. For example, the heat dissipation structure 400 may be placed on the second molding layer 260. For example, the heat dissipation structure 400 may be disposed on the upper surface of the second molding layer 260 by an adhesive film, a thermal grease film, a thermal epoxy film, or a film of material containing at least one metal solid particle among these. However, the heat dissipation structure 400 is not limited thereto. The heat dissipation structure 400 may directly contact the upper surface of the second molding layer 260.

According to some example embodiments described above, the cavity CA is formed on the interposer 180, reducing the overall mounting height of the semiconductor package 10c, and thus an additional structure may be placed on the semiconductor package 10c to compensate for the reduced height. Accordingly, the heat dissipation characteristics of the semiconductor package 10c may be improved by additionally arranging the heat dissipation structure 400 on the semiconductor package 10c without increasing the original height of the semiconductor package 10c, and thus the durability and reliability of the semiconductor package 10c may be improved. Further, even though not illustrated, instead of placing additional structures in the second package 200, additional structures may be placed in the first package 100 since the overall height of the semiconductor package 10c is reduced. For example, the height of the first package 100 may be increased as the overall height of the semiconductor package 10c is reduced, and the heat dissipation structure 400 may be additionally placed on the first semiconductor chip 150. Further, the heat dissipation structure 400 may be additionally placed on the first semiconductor chip 150 and the second molding layer 260, respectively.

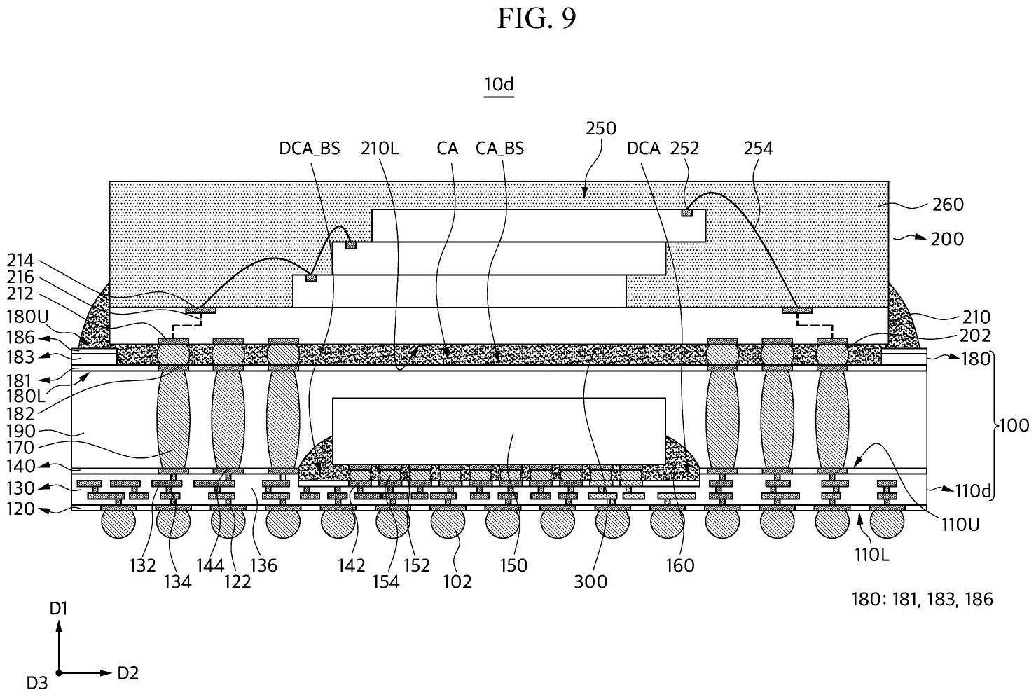

FIG. 9 is a cross-sectional view schematically illustrating a semiconductor package according to some example embodiments.

Referring to a semiconductor package 10d according to some example embodiments, a first package substrate 110d may further include a die cavity DCA. In some example embodiments, the die cavity DCA may be formed on at least a portion of the upper portion of the first package substrate 110d. For example, the die cavity DCA may be formed on the upper surface of the first package substrate 110d, and the die cavity DCA may be a space formed by the first package substrate 110d being indented in a direction from its upper surface to its lower surface. For example, the first package substrate 110d may define the die cavity DCA as an indentation in at least apportion in the upper surface of the first package substrate 110d. Further, when viewed in the first direction D1, the die cavity DCA may be formed in an area that generally overlaps the first semiconductor chip 150. Further, according to some example embodiments, when viewed in the first direction D1, the die cavity DCA may be formed in an area overlapping the first bumps 154 located in the lower portion of the first semiconductor chip 150. In some example embodiments, when viewed in the first direction D1, a bottom surface DCA_BS of the die cavity DCA may be located on the lower side of the upper surface of the first package substrate 110d. For example, the vertical distance from the lower surface of the first package substrate 110d to the upper surface of the first package substrate 110d may be greater than the vertical distance from the lower surface of the first package substrate 110d to the bottom surface DCA_BS of the die cavity DCA.

In some example embodiments, the first bump 154 may be accommodated inside the die cavity DCA. Further, the first pad 152 described above may be placed on the bottom surface DCA_BS of the die cavity DCA. Accordingly, the first bump 154 accommodated inside the die cavity DCA may be electrically connected to the first pad 152 arranged on the bottom surface DCA_BS of the die cavity DCA. Further, the first underfilling film 160 is interposed in the die cavity DCA in order for the gap between the first semiconductor chip 150 and the die cavity DCA to be filled with the first underfilling film 160.

According to some example embodiments described above, the mounting height of the second package 200 and the mounting height of the first semiconductor chip 150 may be further reduced by the cavity CA formed on the interposer 180 and the die cavity DCA formed on the first package substrate 110d. Accordingly, the overall height of the semiconductor package 10d may be reduced (and/or minimized), expanding the mounting flexibility for external components. Further, since an additional space may be secured to additionally place the heat dissipation structure 400 (see FIG. 8), the heat dissipation structure 400 may be easily placed on each of the first semiconductor chips 150 and the second molding layer 260 to increase (and/or maximize) the heat dissipation characteristics of the semiconductor package 10d. Since the first semiconductor chip 150 is mounted in the die cavity DCA and the gap between the first semiconductor chip 150 and the die cavity DCA is filled by the first underfilling film 160, the die cavity DCA may perform a dam function to improve the mounting stability of the first semiconductor chip 150 and the structural stability of the first underfilling film 160.

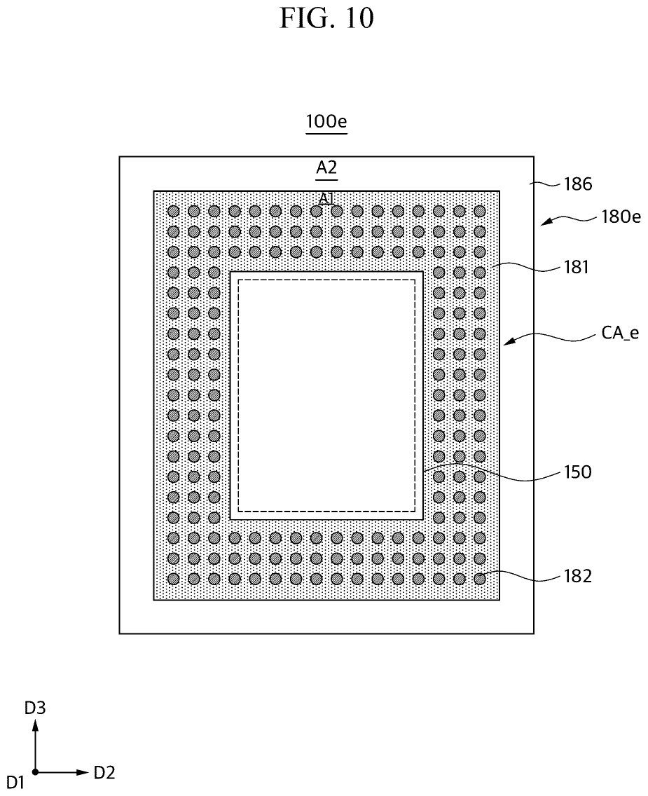

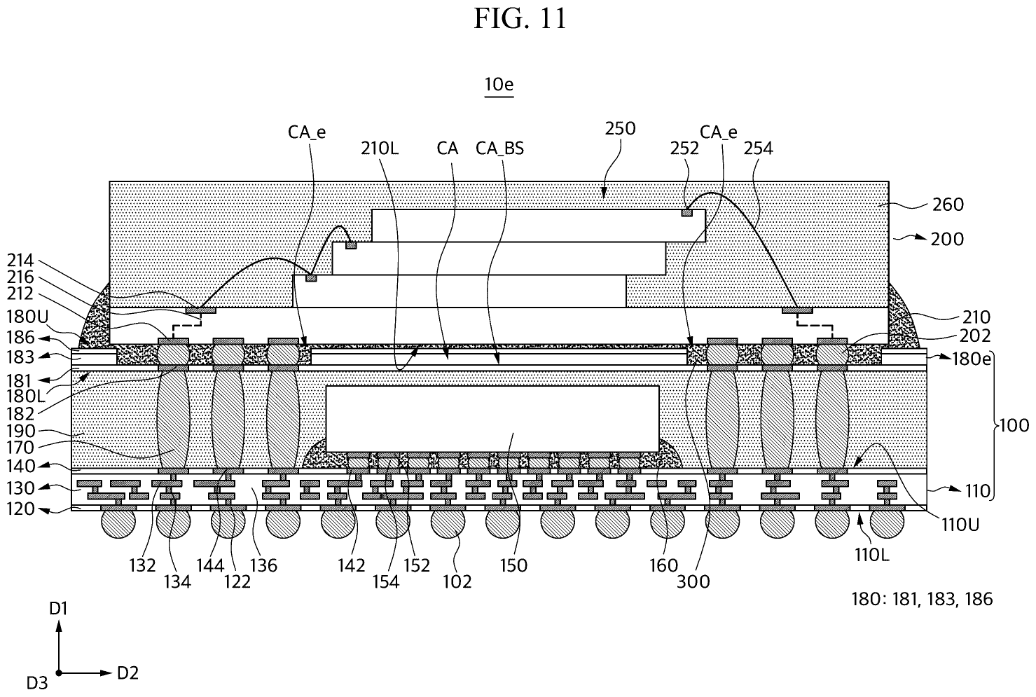

FIG. 10 is a plan view schematically illustrating a second package 100e included in a semiconductor package according to some example embodiments. FIG. 11 is a cross-sectional view schematically illustrating the semiconductor package of FIG. 10. In FIG. 10, some areas described below are shaded to help understanding.

Referring to FIG. 10 and FIG. 11, a cavity CA_e according to some example embodiments may be formed in the core area A1 of an interposer 180e. In some example embodiments, the core area A1 may refer to the area surrounding the first semiconductor chip 150 in the first direction D1. For example, the core area A1 may be an area that substantially overlaps the conductive connecting bodies 170 in the first direction D1. Further, it is apparent that the core area A1 may be an area that substantially overlaps the third connection pads 182 in the first direction D1. Further, the core area A1 may be an area facing the second connection terminals 202 in the first direction D1. In some example embodiments, as illustrated in FIG. 10, the core area A1 may have a roughly rectangular band shape when viewed from the first direction D1. Accordingly, when viewed from the side, the interposer 180e according to some example embodiments may have a structure in which each of the first interposer insulation layer 181, the interposer wiring layer 183 and the second interposer insulation layer 186 is placed in the center and the edge portions, but the interposer 180e according to some example embodiments may have a structure in which the cavity CA_e is formed in the middle part between the center and the edge portions. In some example embodiments described above, since the area where the cavity CA_e is formed is reduced, the manufacturing process of a semiconductor package 10e may be simplified. Thus, the time and cost required for the process may be reduced (and/or minimized), and the overall height of the semiconductor package 10e may be reduced. The concept of shape, placement and arrangement of the cavity CA_e according to some of the some example embodiments may be applied identically or similarly to the die cavity DCA (see FIG. 9).

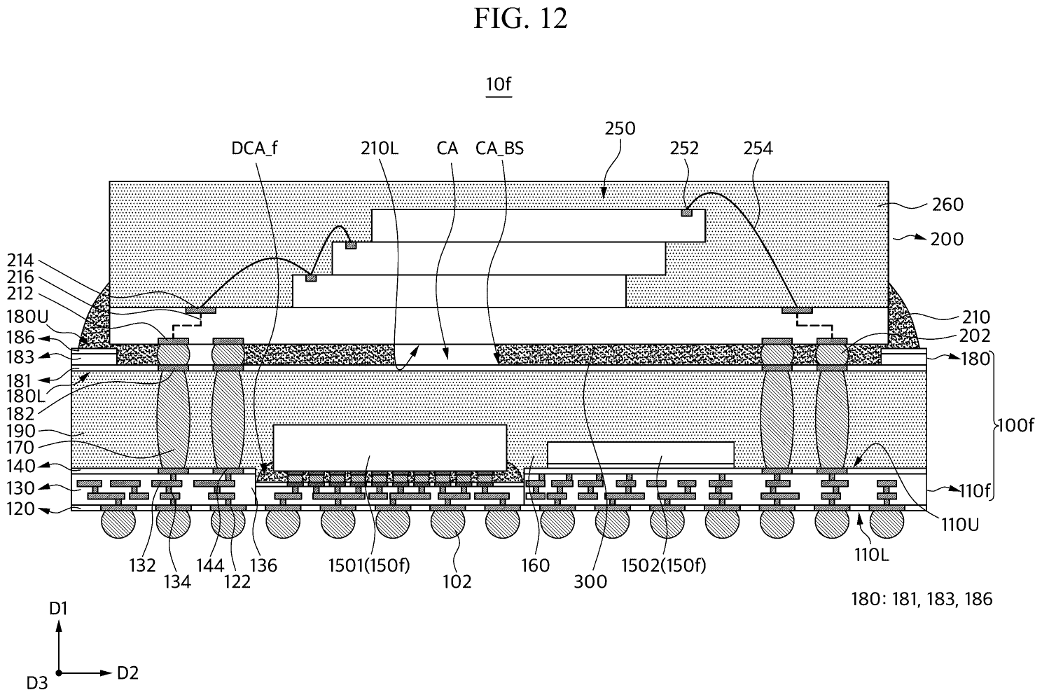

FIG. 12 is a cross-sectional view schematically illustrating a semiconductor package 10f according to some example embodiments.

Referring to FIG. 12, in some example embodiments, a first semiconductor chip 150f of a first package 100f may include a plurality of first semiconductor chips 1501 and 1502. The plurality of first semiconductor chips 1501 and 1502 may include logic chips. However, the present disclosure is not limited thereto. The plurality of first semiconductor chips 1501 and 1502 may include memory chips, one of the plurality of first semiconductor chips 1501 and 1502 may be a logic chip and the other may be a memory chip. Further, the plurality of first semiconductor chips 1501 and 1502 may have different heights. For example, the first semiconductor chip 1501 may be taller than the first semiconductor chip 1502 in height. In some example embodiments, the plurality of first semiconductor chips 1501 and 1502 may have the same height, and the semiconductor chip 1501 may generate more heat than the first semiconductor chip 1502. Further, in some example embodiments, three or more first semiconductor chips 150f may be included.

In some example embodiments, any one first semiconductor chip 1501 that is relatively taller in height or with relatively high heat generation may be accommodated in a die cavity DCA_f formed on a first package substrate 110f. For example, the first package substrate 110f may define the die cavity DCA_f therein. Here, the die cavity DCA_f may be formed at a location overlapping the first semiconductor chip 1501, which is relatively taller in height or with relatively high heat generation in the first direction D1. For example, the die cavity DCA_f described above may be shifted on the first package substrate 110f and selectively formed in some areas. Further, it is apparent that the die cavity DCA_f may be filled with the first underfilling film 160.

In some of the some example embodiments, when multiple semiconductor chips are mounted on a package substrate, an area where the die cavity DCA_fis formed on the first package substrate 110f may be varied depending on the structure and heat generation characteristics of each semiconductor chip. For example, for semiconductor chips that generate relatively high heat, by selectively forming a die cavity on the mounting area and filling the die cavity with an underfilling film, resistance to heat generated from the semiconductor chip may be enhanced. Further, for example, for semiconductor chips with relatively tall structures, by selectively forming a die cavity on the mounting area, the increase in the overall height of the semiconductor package due to the semiconductor chip with a relatively large mounting height may be reduced (and/or minimized).

The above some example embodiments may be applied identically or similarly to the cavity CA formed on the interposer 180 described above with reference to FIG. 3. For example, even when a plurality of second packages 200 are provided, depending on the structural characteristics and/or heat generation characteristics of the second package 200, the cavity CA may be formed by shifting on the interposer 180.

Some example embodiments described above may be combined in various forms and reconfigured into further modified example embodiments as long as they are not technically contradictory and unless there are special circumstances that make the various forms technically impossible.

The above detailed description is illustrative of the present disclosure. Further, the above description illustrates and explains some example embodiments of the present disclosure, and the present disclosure may be used in various other combinations, modifications, and environments. For example, changes and modifications are possible in the scope of the present disclosure, the scope that is equivalent to the above description and/or the scope of technology or knowledge in the art. The above some example embodiments describe implementations of the technical ideas of the present disclosure, and various modifications are also possible as required for specific application fields and uses of the present disclosure. Therefore, the detailed description of the present disclosure is not intended to limit the present disclosure to the described some example embodiments. Further, the appended claims should be construed to include other some example embodiments.

What is claimed is:

1. A semiconductor package comprising:
a first package substrate comprising a first surface and a second surface, the second surface being opposite to the first surface;
a first semiconductor chip on the second surface of the first package substrate;
an interposer comprising a third surface and a fourth surface, the fourth surface being opposite to the third surface, and the third surface facing the first semiconductor chip;
a second package substrate on the interposer, and a connection terminal being between the second package substrate and the interposer; and
a second semiconductor chip on the second package substrate,
wherein the interposer defines a cavity that is an indentation in at least a portion of the fourth surface, and the connection terminal is in the cavity.

2. The semiconductor package of claim 1, wherein a vertical distance from the third surface to a bottom surface of the cavity is smaller than a vertical distance from the third surface to the fourth surface.

3. The semiconductor package of claim 2, further comprising an underfilling film configured to fill a gap between the cavity and the second package substrate, and a gap between the fourth surface and the second package substrate.

4. The semiconductor package of claim 1, wherein the interposer comprises:
a first interposer insulation layer comprising the third surface;
a second interposer insulation layer comprising the fourth surface; and
an interposer wiring layer between the first interposer insulation layer and the second interposer insulation layer,
wherein a bottom surface of the cavity is at a vertical level identical to a vertical level of an upper surface of the first interposer insulation layer, and
wherein the connection terminal contacts a connection pad in the first interposer insulation layer.

5. The semiconductor package of claim 1, wherein the interposer comprises:
a first interposer insulation layer comprising the third surface;
a second interposer insulation layer comprising the fourth surface; and
an interposer wiring layer between the first interposer insulation layer and the second interposer insulation layer,
wherein a bottom surface of the cavity is at a vertical level that is identical to a vertical level of an upper surface of the interposer wiring layer, and
wherein the connection terminal contacts a wiring line within the interposer wiring layer.

6. The semiconductor package of claim 1, wherein at least a portion of the second package substrate overlaps the interposer in a vertical direction with respect to a bottom surface of the cavity.

7. The semiconductor package of claim 1, wherein
a vertical distance from the first surface to a lower surface of the second package substrate is greater than a vertical distance from the first surface to the fourth surface, and
at least a portion of the second package substrate overlaps a side of the cavity in a vertical direction.

8. The semiconductor package of claim 7, wherein
a terminal gap is between the lower surface of the second package substrate and a bottom surface of the cavity, and a filled gap is between the lower surface of the second package substrate and the fourth surface, and
the filled gap is narrower than the terminal gap.

9. The semiconductor package of claim 1, wherein
a vertical distance from the first surface to a lower surface of the second package substrate is less than a vertical distance from the first surface to the fourth surface, and
the second package substrate is on an inner side of the cavity.

10. The semiconductor package of claim 9, wherein
a terminal gap is between the lower surface of the second package substrate and a bottom surface of the cavity, and a filled gap is between a side of the second package substrate and the inner side of the cavity, and
the filled gap is narrower than the terminal gap.

11. The semiconductor package of claim 1, wherein
the first package substrate defines a die cavity as an indentation in at least a portion of the second surface,
a first bump is on a lower portion of the first semiconductor chip inside the die cavity, and
the semiconductor package further comprises an underfilling film configured to fill a gap between the die cavity and the first semiconductor chip.

12. The semiconductor package of claim 1, further comprising a heat dissipation structure on the second package substrate.

13. The semiconductor package of claim 1, wherein the interposer defines the cavity as having a rectangular band shape on at least a portion of the fourth surface.

14. The semiconductor package of claim 1, wherein
the fourth surface comprises a core area comprising a center of the fourth surface and a sub area configured to surround the core area, and
the at least a portion of the fourth surface is the core area.

15. The semiconductor package of claim 1, wherein
the fourth surface comprises a core area comprising a center of the fourth surface and a sub area configured to surround the core area, and
the at least a portion of the fourth surface is a portion where a conductive connection body vertically connects the first package substrate and the interposer in the core area.

16. A semiconductor package comprising:
an interposer comprising a first surface and a second surface, the second surface being opposite to the first surface, and the interposer defining a cavity that is an indentation in at least a portion of the second surface;
a structure on the second surface of the interposer;
a plurality of connecting structures in the cavity, and the plurality of connecting structures being configured to electrically connect the interposer and the structure; and
an underfilling film configured to fill a gap between the interposer and the structure.

17. The semiconductor package of claim 16, wherein
the interposer comprises an interposer insulation layer and an interposer wiring layer, and
a bottom surface of the cavity is at a vertical level that is identical to a vertical level of the interposer insulation layer.

18. The semiconductor package of claim 16, wherein the gap between the interposer and the structure is narrower than a gap between the structure and a bottom of the cavity.

19. The semiconductor package of claim 16, wherein the cavity is on an area that vertically overlaps an area of the plurality of connecting structures.

20. A semiconductor package comprising:
a first package substrate comprising a first surface and a second surface, the second surface being opposite to the first surface;
a first semiconductor chip on the second surface of the first package substrate;
an interposer comprising a third surface and a fourth surface, the third surface facing the first semiconductor chip, the fourth surface being opposite to the third surface, and the interposer defining a cavity that is an indentation in at least a portion of the fourth surface;
conductive connecting bodies surrounding the first semiconductor chip, the conductive connecting bodies being configured to vertically connect the first package substrate and the interposer;
a second package substrate on the fourth surface of the interposer;
a second semiconductor chip on the second package substrate;
a connection terminal inside the cavity, the connection terminal being electrically connected to a conductive connecting body from among the conductive connecting bodies; and
an underfilling film configured to fill a gap between the interposer at the cavity and the second package substrate,
wherein the cavity is in an area vertically overlapping with an area of the connection terminal.
